(19) United States
(12) Patent Application Publication
(10) Pub. No.: US 2025/0308587 A1
(43) Pub. Date: Oct. 2, 2025

(54) RAM

(71) Applicant: ROHM CO., LTD., Kyoto (JP)

(72) Inventors: Kosuke IJIGAWA, Kyoto (JP); Kazuhisa UKAI, Kyoto (JP)

(21) Appl. No.: 19/092,194

(22) Filed: Mar. 27, 2025

(30) Foreign Application Priority Data
Mar. 29, 2024 (JP) 2024-055984

(51) Int. Cl. G11C 11/419

(52) U.S. Cl. CPC G11C 11/419

(57) ABSTRACT

A RAM includes a first bit line and a second bit line arranged on different layers. One of the first bit line and the second bit line has a first connection line formed on the same layer as the other of the first bit line and the second bit line, so as to be connected to a memory cell. A first inverted bit line and a second inverted bit line are arranged on different layers, and one of the first inverted bit line and the second inverted bit line has a second connection line formed on the same layer as the other of the first inverted bit line and the second inverted bit line, so as to be connected to the memory cell.

### CROSS-REFERENCE TO RELATED APPLICATIONS

This nonprovisional application claims priority under 35 U.S.C. § 119 (a) to Patent Application No. 2024-55984 filed in Japan on Mar. 29, 2024, the entire contents of which are hereby incorporated by reference.

### BACKGROUND OF THE INVENTION

### Field of the Invention

The present disclosure relates to a random access memory (RAM), in more detail, a multiport RAM including a dual port RAM and a 2-port RAM.

### Description of Related Art

Conventionally, a RAM can perform reading data from a first memory cell and writing data to a second memory cell simultaneously or substantially simultaneously. Such a RAM can perform data processing at high speed. It is known that an interference between ports can be generated in such a RAM.

Note that Patent Document 1 (WO2007/018043) can be cited as an example of a conventional technique related to the above.

### BRIEF DESCRIPTION OF THE DRAWINGS

FIG. 1 is a schematic block diagram of a dual port RAM according to this embodiment.

FIG. 2 is a circuit diagram illustrating a basic structure of a memory cell.

FIG. 3 is a timing chart illustrating voltage waveforms at individual points of the dual port RAM according to this embodiment.

FIG. 4 is a diagram illustrating a part of the dual port RAM according to this embodiment.

FIG. 5 is a diagram illustrating a part of the dual port RAM according to this embodiment.

FIG. 6 is a schematic diagram illustrating a wiring layout of the dual port RAM.

FIG. 7 is a schematic layout diagram of wirings of layers on which bit lines, a power supply line, and a ground line are formed.

### DETAILED DESCRIPTION OF THE PREFERRED EMBODIMENTS

In this specification, a metal oxide semiconductor (MOS) field effect transistor means a field effect transistor having a gate structure consisting of at least three layers including a layer made of a conductor or a semiconductor such as polysilicon having a small resistance, an insulation layer, and a P-type, N-type, or intrinsic semiconductor layer. In other words, the gate structure of the MOS field effect transistor is not limited to a three-layered structure made of metal, oxide, and semiconductor. In addition, an N-channel type MOS field effect transistor is referred to as an NMOS transistor, and a P-channel type MOS field effect transistor is referred to as a PMOS transistor.

### <Dual Port RAM>

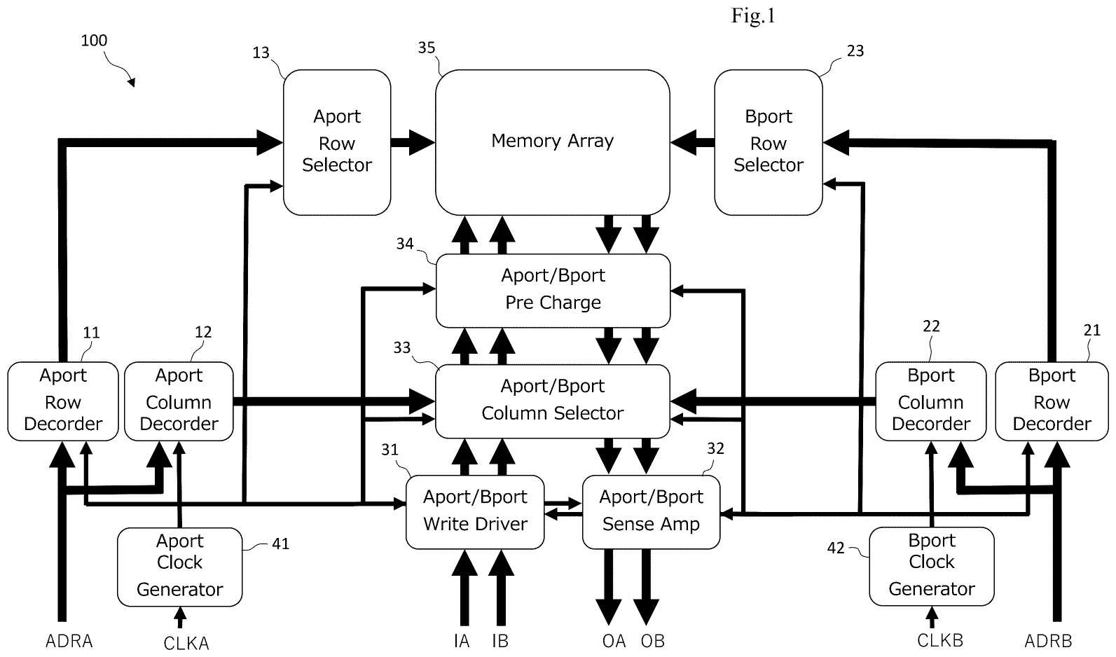

FIG. 1 is a schematic block diagram of a dual port RAM 100.

The dual port RAM 100 has a A-port as a first input/output port and a B-port as a second input/output port, which are independent of each other.

The dual port RAM 100 includes a row decoder 11 dedicated for the A-port, a column decoder 12 dedicated for the A-port, and a row selector 13 dedicated for the A-port.

The row decoder 11 supplies the row selector 13 with row information obtained by decoding an A-port address ADRA supplied from the A-port.

The column decoder 12 supplies a column selector 33 that will be described later with column information obtained by decoding the A-port address ADRA supplied from the A-port.

The row selector 13 selects a row of a memory array 35 that will be described later, on the basis of the row information supplied from the row decoder 11.

The dual port RAM 100 includes a row decoder 21 dedicated for the B-port, a column decoder 22 dedicated for the B-port, and a row selector 23 dedicated for the B-port.

The row decoder 21 supplies the row selector 23 with row information obtained by decoding a B-port address ADRB supplied from the B-port.

The column decoder 22 supplies the column selector 33 that will be described later with column information obtained by decoding the B-port address ADRB supplied from the B-port.

The row selector 23 selects a row of the memory array 35 that will be described later, on the basis of the row information supplied from the row decoder 21.

The dual port RAM 100 includes a write driver 31, a sense amplifier 32, the column selector 33, and a precharge circuit 34.

When the write driver 31 receives a write command and input data IA from the A-port, it writes the input data IA to a memory cell in the memory array 35 selected on the basis of the A-port address ADRA, via the column selector 33 and the precharge circuit 34. In addition, when the write driver 31 receives the write command and input data IB from the B-port, it writes the input data IB to a memory cell in the memory array 35 selected on the basis of the B-port address ADRB, via the column selector 33 and the precharge circuit 34.

When the sense amplifier 32 receives a read command from the A-port, it reads data from a memory cell in the memory array 35 selected on the basis of the A-port address ADRA, via the column selector 33 and the precharge circuit 34, and outputs the read data as output data OA to the A-port. When the sense amplifier 32 receives the read command from the B-port, it reads data from a memory cell in the memory array 35 selected on the basis of the B-port address ADRB, via the column selector 33 and the precharge circuit 34, and outputs the read data as output data OB to the B-port.

The column selector 33 selects a column for the A-port of the memory array 35 on the basis of the column information supplied from the column decoder 12. In addition, the column selector 33 selects a column for the B-port of the memory array 35 on the basis of the column information supplied from the column decoder 22.

The precharge circuit 34 precharges the column (a bit line) of the memory array 35 in a standby state.

The memory array 35 includes a plurality of memory cells 50 arranged like a matrix. Details of the memory cell 50 are described below.

### <Memory Cell 50>

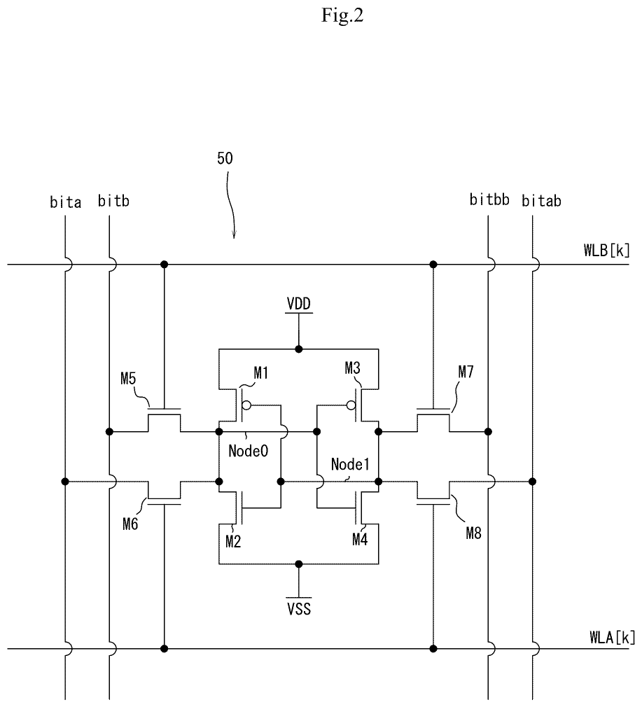

FIG. 2 is a circuit diagram illustrating a basic structure of the memory cell 50. FIG. 2 illustrates a circuit structure of a k-th memory cell 50. Note that in the following description, if it is necessary to identify the memory cell 50, the k-th memory cell 50 is referred to as a memory cell 50[k]. The memory cell 50 illustrated in FIG. 2 has a 6T structure (i.e., a structure consisting of six transistors). The memory cell 50 includes NMOS transistors M2 and M4, PMOS transistors M1 and M3, and NMOS transistors M5, M6, M7, and M8. In the following description, for convenience sake of description, they are referred to as transistors M1 to M8 for short. Note that the transistors M5 to M8 may be configured to be included in the memory cell 50 or not included in the same.

The sources of the transistors M1 and M3 are both connected to a power supply line VDD (i.e., an application terminal of a power supply voltage). The drains of the transistors M1 and M2 and the gates of the transistors M3 and M4 are all connected to an internal node Node0. The drains of the transistors M3 and M4 and the gates of the transistors M1 and M2 are all connected to an internal node Node1. The sources of the transistors M2 and M4 are both connected to a ground line VSS (i.e., an application terminal of a ground voltage GND).

Note that the transistors M1 and M2 constitutes an inverter having an input terminal connected to the internal node Node1 and an output terminal connected to the internal node Node0. In addition, the transistors M3 and M4 constitutes an inverter having an input terminal connected to the internal node Node0 and an output terminal connected to the internal node Node1. In other words, the transistors M1 to M4 function as an inverter loop connected between the internal node Node0 and the internal node Node1.

The transistor M5 is connected between the internal node Node0 and a second bit line bitb, and is turned on/off in accordance with an applied voltage to a word line WLB[k] connected to the gate. The transistor M6 is connected between a first bit line bita and the drains of the transistors M1 and M2, and is turned on/off in accordance with an applied voltage to a word line WLA [k] connected to the gate.

The transistor M7 is connected between a second inverted bit line bitbb and the drains of the transistors M3 and M4, and is turned on/off in accordance with an applied voltage to the word line WLB[k] connected to the gate. The transistor M8 is connected between the internal node Node1 and a first inverted bit line bitab, and is turned on/off in accordance with an applied voltage to the word line WLA [k] connected to the gate.

Note that in the dual port RAM 100, the write driver 31, the sense amplifier 32, the column selector 33, the precharge circuit 34 are all configured to receive information or a command from both the A-port and the B-port so as to perform their corresponding operations, but this is not a limitation. The dual port RAM 100 may include the write drivers 31, the sense amplifiers 32, the column selectors 33, and the precharge circuits 34, dedicated for the A-port and dedicated for the B-port, respectively.

The dual port RAM 100 includes a signal generator 41 dedicated for the A-port and a signal generator 42 dedicated for the B-port.

The signal generator 41 generates a one-shot pulse signal 1shotA synchronizing with a clock signal CLKA supplied from the A-port. The signal generator 41 supplies the one-shot pulse signal 1shotA to the row decoder 11, the column decoder 12, the row selector 13, the write driver 31, the sense amplifier 32, the column selector 33, and the precharge circuit 34.

The signal generator 42 generates a one-shot pulse signal 1shotB synchronizing with a clock signal CLKB supplied from the B-port. The clock signal CLKA and the clock signal CLKB are asynchronous with each other. The signal generator 42 supplies the one-shot pulse signal 1shotB to the row decoder 21, the column decoder 22, the row selector 23, the write driver 31, the sense amplifier 32, the column selector 33, and the precharge circuit 34.

Next, an interference between ports is described.

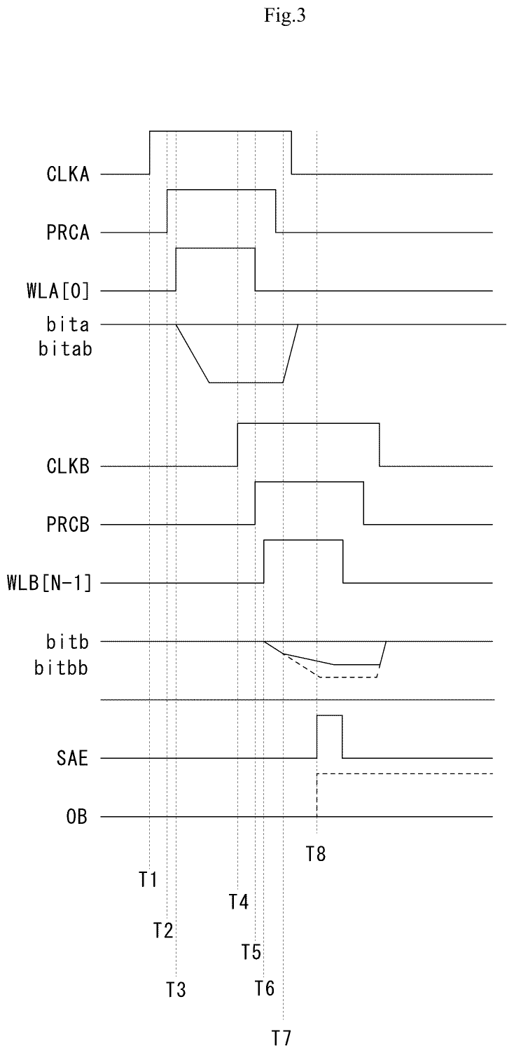

FIG. 3 is a timing chart illustrating voltage waveforms at individual points of the dual port RAM 100, in a case where the A-port receives the write command while the read command is received from the B-port, so that write and read are performed on different memory cells of the same column. As illustrated in FIG. 3, the RAM 100 can perform a write operation and a read operation in different memory cells 50 in one cycle.

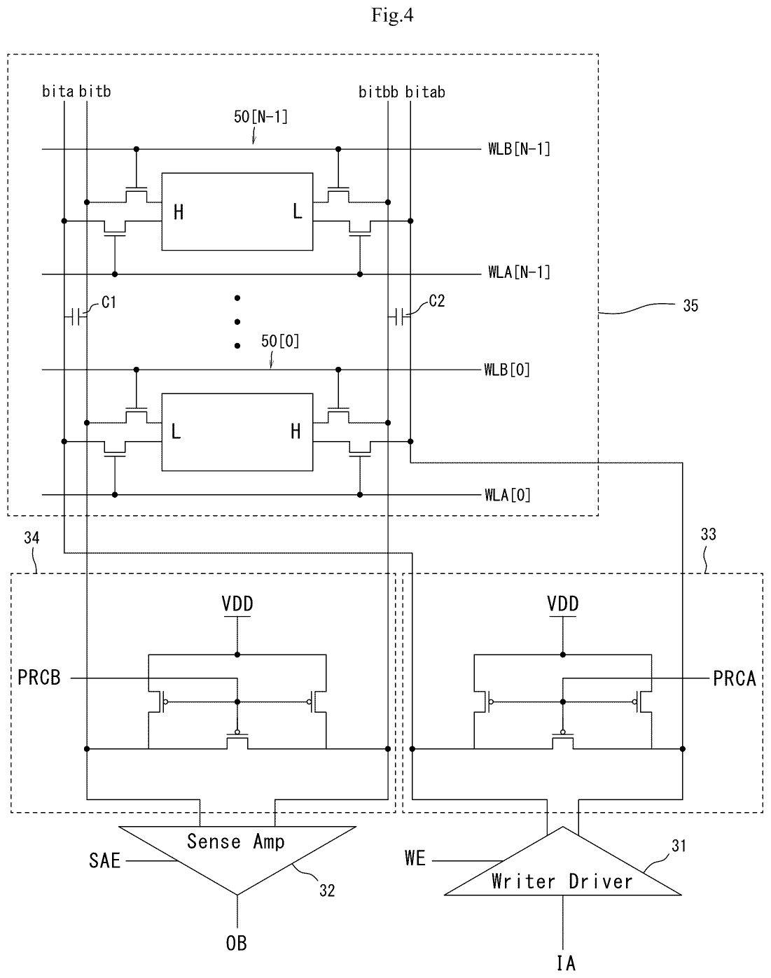

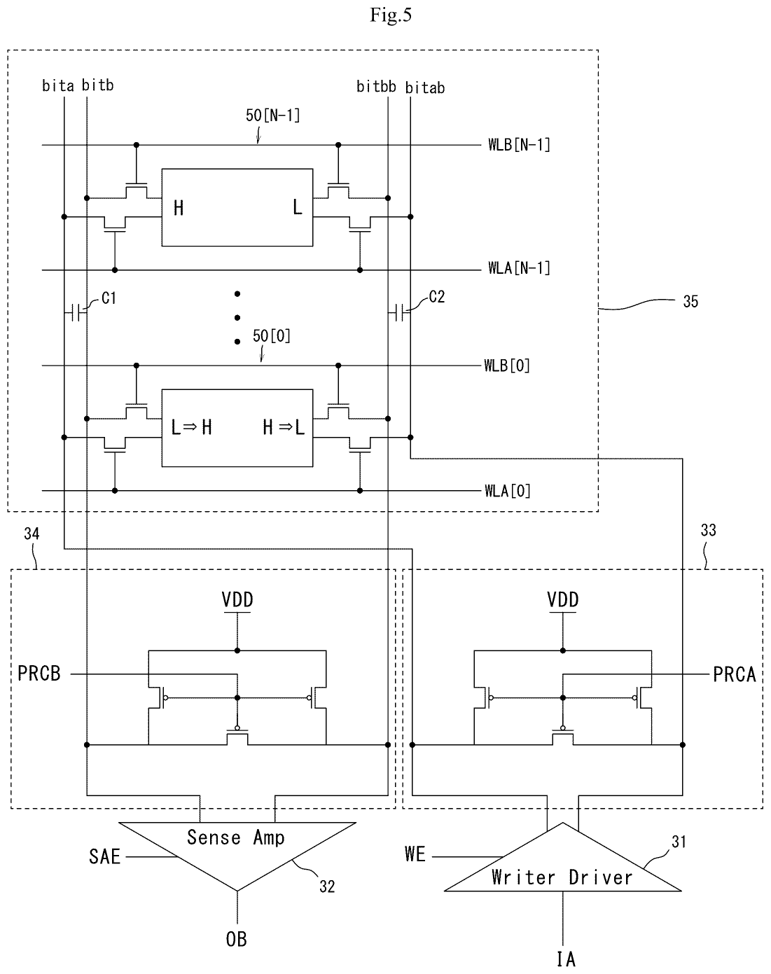

FIGS. 4 and 5 are diagrams illustrating a relevant part of the dual port RAM 100 according to a comparative example, in a case where the A-port receives the write command while the read command is received from the B-port, so that write and read are performed on different memory cells of the same column.

FIG. 3 illustrates an operation in a case where data is written to a memory cell 50[0] while data is read from a memory cell 50[N−1]. As illustrated in FIG. 3, the write operation is started at first timing T1 (see FIG. 3) at which a rising edge of the clock signal CLKA appears.

Next, at second timing T2 (see FIG. 3) at which a precharge control signal PRCA is switched from LOW level to HIGH level, the first bit line bita and the first inverted bit line bitab become a floating state.

Next, at third timing T3 (see FIG. 3), a voltage applied to a word line WLA [0] is switched from LOW level to HIGH level, and as illustrated in FIG. 5, data corresponding to the input data IA is written to the memory cell 50[0]

Next, at fourth timing T4 (see FIG. 3) at which a rising edge of the clock signal CLKB appears, the read operation is started.

Next, at fifth timing T5 (see FIG. 3) at which a precharge control signal PRCB is switched from LOW level to HIGH level, the second bit line bitb and the second inverted bit line bitbb become the floating state.

Next, at sixth timing T6 (see FIG. 3), a voltage applied to a word line WLB [N−1] is switched from LOW level to HIGH level, and the second inverted bit line bitbb is discharged by the memory cell 50[N−1].

After that, the write operation is finished, the precharge control signal PRCA is switched from HIGH level to LOW level, and at seventh timing T7 (see FIG. 3), the first inverted bit line bitab is switched from LOW level to HIGH level.

The first inverted bit line bitab and the second inverted bit line bitbb are arranged in parallel, and hence a parasitic capacitance C2 is formed between the first inverted bit line bitab and the second inverted bit line bitbb (see FIGS. 4 and 5). A signal of the first inverted bit line bitab and a signal of the second inverted bit line bitbb have opposite phases to each other, and hence there is noise on the second inverted bit line bitbb as an influence of capacitive cross talk due to the parasitic capacitance C2.

In FIG. 3, an ideal voltage of the second inverted bit line bitbb is shown by a broken line, and a solid line shows a voltage of the second inverted bit line bitbb that was not sufficiently discharged because of an influence of the interference between ports. If there is noise on the second inverted bit line bitbb by the capacitive cross talk due to the parasitic capacitance C2 as described above, discharge of the second inverted bit line bitbb is disturbed, and the voltage applied to the second inverted bit line bitbb is insufficiently dropped.

After that, at eighth timing T8 (see FIG. 3), a sense amplifier enable signal SAE is switched from LOW level to HIGH level, and the sense amplifier 32 determines a logic of the difference between a voltage applied to the second bit line bitb and the voltage applied to the second inverted bit line bitbb, so as to fix the read data.

In FIG. 3, correct output data OB is shown by a broken line, and incorrect output data OB due to the influence of the interference between ports is shown by a solid line. As illustrated in FIG. 3, if the drop of the voltage of the second inverted bit line bitbb is insufficient, the difference between the voltage applied to the second bit line bitb and the voltage applied to the second inverted bit line bitbb is small. Further, if the difference between the voltage applied to the second bit line bitb and the voltage applied to the second inverted bit line bitbb is less than a voltage difference whose logic can be determined by the sense amplifier 32, incorrect output data OB (the solid line in FIG. 3) is read out.

In addition, there is a case where the memory cell 50[N−1] is written while the memory cell 50[0] is read, and also in this case, there is an influence of similar cross talk. Further, a parasitic capacitance C1 is also formed between the first bit line bita and the second bit line bitb, in the same manner. Incorrect data may be read out also by cross talk due to the parasitic capacitance C1.

### <Device Structure>

The dual port RAM 100 according to this embodiment has a device structure in which the parasitic capacitance C1 is reduced, so that the influence of the interference between ports can be reduced. Hereinafter, the device structure of the dual port RAM 100 according to this embodiment is described with reference to the drawings.

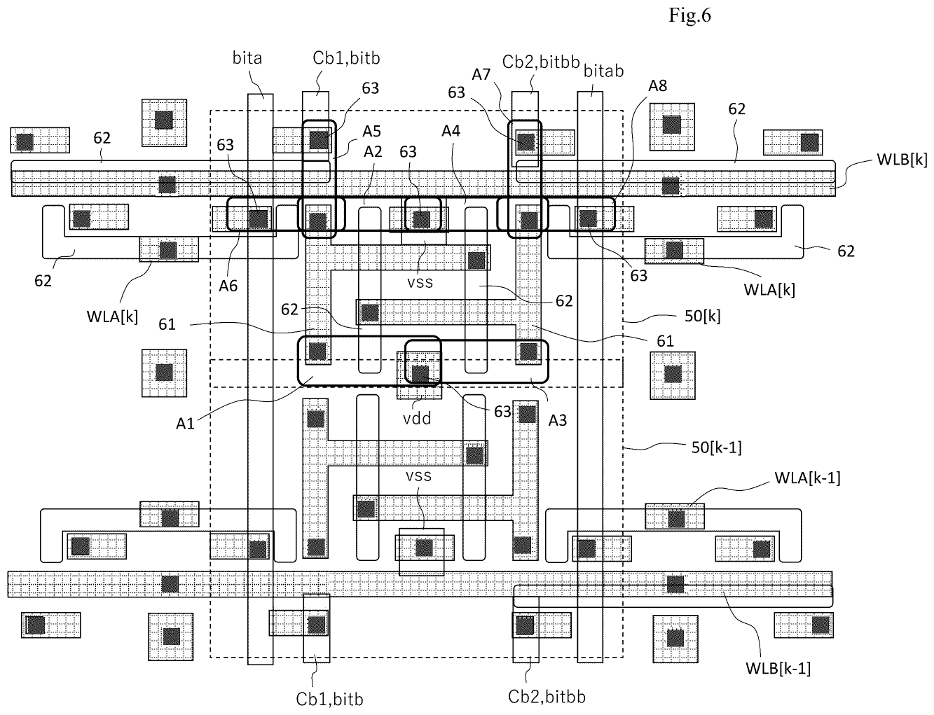

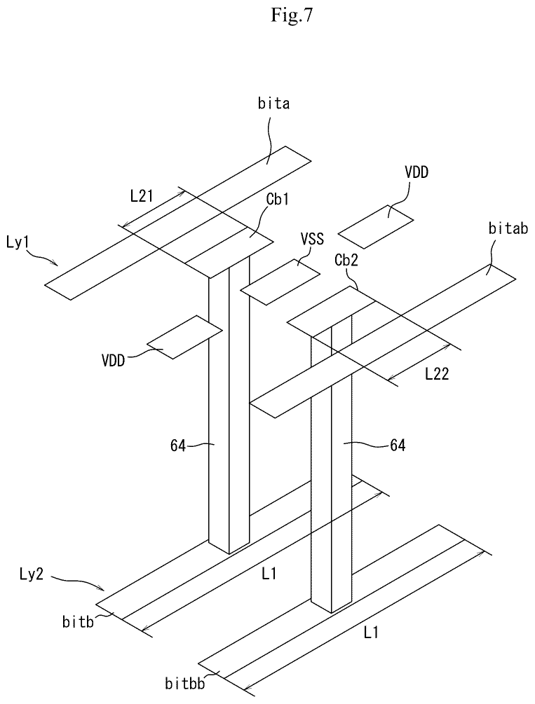

FIG. 6 is a schematic diagram illustrating a wiring layout of the dual port RAM. FIG. 7 is a schematic diagram that schematically illustrates layers on which bit lines and contacts are arranged. FIG. 6 illustrates the k-th memory cell 50[k] and the (k−1)th memory cell 50[k−1] among a plurality of memory cells. Note that in FIG. 6, active areas A1 to A8 are described with reference to the k-th memory cell 50[k], and the (k−1)th memory cell 50[k−1] has the same structure.

As illustrated in FIG. 6, the dual port RAM 100 includes the active areas A1 to A8, metal wirings 61, gate wirings 62 and contacts 63. In FIG. 6, the metal wirings 61 are hatched in a grid pattern. In addition, the active areas A1 to A8 are enclosed by a thick line. Further, the contacts 63 are shown in solids.

As illustrated in FIG. 6, the dual port RAM 100 includes the first active area A1, the second active area A2, the third active area A3, the fourth active area A4, the active area A5, the active area A6, the active area A7, and the active area A8.

The active areas A1 to A8 constitute the transistors M1 to M8, respectively. Further, both ends of each of the active areas A1 to A8 are respectively the source and the drain of each of the transistors M1 to M8, and the middle part thereof is the gate. The both ends of the active areas A1 to A8 are respectively overlapped with the metal wirings 61. The sources and the drains of the active areas A1 to A8 are electrically connected to the metal wirings 61 via the contacts 63, and each of the active areas A1 to A8 is supplied with any one of signals from the bit lines, the power supply voltage, and the ground voltage, via the metal wiring 61.

The gate wiring 62 is connected via the contact 63 to the metal wiring 61 that is connected to one of the bit lines, or to the metal wiring 61 that is connected to one of the word lines. The gate wiring 62 is supplied with a signal from each bit line or word line. The gate wiring 62 is connected to a part forming the gate of the transistor M1 to M8 formed in the active area A1 to A8. The transistor M1 to M8 formed in the active area A1 to A8 is driven by the signal supplied from the gate wiring 62.

The dual port RAM 100 has two wiring layers, i.e., a first layer Ly1 and a second layer Ly2. The first bit line bita and the first inverted bit line bitab are arranged on the first layer Ly1. The first bit line bita and the metal wiring 61, as well as the first inverted bit line bitab and the metal wiring 61 are electrically connected to each other via the contact 63. In addition, a first connection line Cb1 disposed in parallel to the first bit line bita, and a second connection line Cb2 disposed in parallel to the first inverted bit line bitab are arranged on the first layer Ly1. Further, on the first layer Ly1, the first bit line bita, the first inverted bit line bitab, the first connection line Cb1, and the second connection line Cb2 are electrically connected to the metal wirings via the contacts 63, respectively.

The second bit line bitb and the second inverted bit line bitbb are arranged on the second layer Ly2 that is a wiring layer different from the first layer Ly1. The second bit line bitb and the second inverted bit line bitbb extend along a column direction (Y direction). Further, the second bit line bitb and the first connection line Cb1, which are arranged on the different layers, are electrically connected to each other through a via 64. In addition, the second inverted bit line bitbb and the second connection line Cb2, which are arranged on the different layers, are electrically connected to each other through the via 64. In other words, a signal from the second bit line bitb is supplied to the active area A5 via the first connection line Cb1. In addition, a signal from the second inverted bit line bitbb is supplied to the active area A7 via the second connection line Cb2.

In the dual port RAM 100, an input/output port is disposed at an end on one side in the column direction (Y direction). For this reason, the first bit line bita, the second bit line bitb, the first inverted bit line bitab, and the second inverted bit line bitbb need to have at least a length necessary for electrically connecting to each of the memory cells 50 arranged in the column direction. In other words, the first bit line bita, the second bit line bitb, the first inverted bit line bitab, and the second inverted bit line bitbb are configured to have a length L1 in the column direction (Y direction).

Further, the first connection line Cb1 has a length L21 in the column direction (Y direction) that is shorter than the length L1 of the second bit line bitb in the column direction (Y direction). Further, the second connection line Cb2 has a length L22 in the column direction (Y direction) that is shorter than the length L1 of the second inverted bit line bitbb in the column direction (Y direction).

In the dual port RAM 100, the first bit line bita and the second bit line bitb, which are disposed in parallel to each other in the column direction (Y direction), are arranged on the first layer Ly1 and the second layer Ly2, respectively, which are different layers. For this reason, the parasitic capacitance C1 is not generated between the first bit line bita and the second bit line bitb. In addition, a signal of the second bit line bitb is sent and received via the first connection line Cb1 connected to the second bit line bitb through the via 64. For this reason, when the write operation and the read operation are performed in the dual port RAM 100, a parasitic capacitance C12 is generated between the first bit line bita and the first connection line Cb1.

The length L21 of the first connection line Cb1 in the column direction is shorter than the length L1 of the second bit line bitb in the column direction. For this reason, the parasitic capacitance C12 is smaller than the parasitic capacitance C1 generated between the first bit line bita and the second bit line bitb, when the first bit line bita and the second bit line bitb are arranged on the same wiring layer. In the dual port RAM 100, the capacitive cross talk due to the parasitic capacitance C12 when the write operation and the read operation are performed is smaller than the capacitive cross talk due to the parasitic capacitance C1. As a result, the influence of the interference between ports in the dual port RAM 100 can be reduced, and write and read of correct information can be performed.

In addition, in the dual port RAM 100, the first inverted bit line bitab and the second inverted bit line bitbb, which are disposed in parallel to each other in the column direction, are arranged on different layers. For this reason, the parasitic capacitance C2 is not generated between the first inverted bit line bitab and the second inverted bit line bitbb. In addition, a signal of the second inverted bit line bitbb is sent and received via the second connection line Cb2 connected to the second inverted bit line bitbb through the via 64. For this reason, when the write operation and the read operation is performed in the dual port RAM 100, the parasitic capacitance C22 is generated between the second bit line bitb and the second connection line Cb2.

The length L22 of the second connection line Cb2 in the column direction is shorter than the length L1 of the second inverted bit line bitbb in the column direction. For this reason, the parasitic capacitance C22 is smaller than the parasitic capacitance C2 generated between the first inverted bit line bitab and the second inverted bit line bitbb, when the first inverted bit line bitab and the second inverted bit line bitbb are arranged on the same wiring layer. When the write operation and the read operation are performed in the dual port RAM 100, the capacitive cross talk due to the parasitic capacitance C22 is smaller than the capacitive cross talk due to the parasitic capacitance C2. As a result, the influence of the interference between ports in the dual port RAM can be reduced, and hence write and read of correct information can be performed.

Note that this embodiment has the structure in which the first bit line bita and the first inverted bit line bitab are arranged on the first layer Ly1 to which the metal wirings 61 can connect, but this is not a limitation. For instance, it may be configured that the first bit line bitb and the first inverted bit line bitbb are arranged on the first layer Ly1 to which the metal wirings 61 can connect.

In addition, it may be configured that one of the first bit line bita and the second bit line bitb is arranged on the first layer Ly1 to which the metal wirings 61 can connect, while the other is arranged on the second layer Ly2, and that one of the first inverted bit line bitab and the second inverted bit line bitbb is arranged on the first layer Ly1 to which the metal wirings 61 can connect, while the other is arranged on the second layer Ly2. In other words, it is preferred to arrange the first bit line bita and the second bit line bitb, which are disposed in parallel to each other, on different layers, and to arrange the first inverted bit line bitab and the second inverted bit line bitbb, which are disposed in parallel to each other, on different layers.

In addition, the dual port RAM 100 is configured to have the two wiring layers Ly1 and Ly2, but this is not a limitation. For instance, it may be configured to have three or more wiring layers. In this structure, it may be configured that the first bit line bita and the second bit line bitb are both arranged on different layers and are electrically connected to the metal wirings 61 via the first connection line. In addition, it may be configured that the first inverted bit line bitab and the second inverted bit line bitbb are both arranged on different layers and are electrically connected to the metal wirings 61 via the second connection line.

### <Others>

The above embodiment is merely an example in every aspect, and should not be interpreted as a limitation. The technical scope of the present disclosure is defined not by the above description of the embodiment but by the claims, which should be understood to include all modifications within meaning and scope equivalent to the claims.

For instance, the RAM according to each embodiment described above is the dual port RAM having the A-port as a first input/output port and the B-port as a second input/output port, which are independent of each other, but it may be possible to use a 2-port RAM having an input-only port and an output-only port, instead of the dual port RAM.

### <Additional Remarks>

Additional remarks are made below for the present disclosure in which specific structural examples are shown in the embodiment described above.

As described above, a RAM (100) may have a structure (first structure) including: a plurality of memory cells (50);
a first bit line (bita) and a first inverted bit line (bitab) connected to each of the plurality of memory cells (50), so as to be used for a write operation to write information to the memory cell (50) or a read operation to read information, on the basis of a first clock signal (CLKA); and
a second bit line (bitb) and a second inverted bit line (bitbb) connected to each of the plurality of memory cells (50), so as to be used for the write operation or the read operation, on the basis of a second clock signal (CLKB) different from the first clock signal (CLKA), wherein
the first bit line (bita) and the second bit line (bitab) are arranged on different layers (Ly1,Ly2), and one of the first bit line (bita) and the second bit line (bitb) is configured to have a first connection line (Cb1) formed on the same layer (Ly1,Ly2) as the other of the first bit line (bita) and the second bit line (bitb), so as to be connected to the memory cell (50), and
the first inverted bit line (bitab) and the second inverted bit line (bitbb) are arranged on different layers (Ly1,Ly2), and one of the first inverted bit line (bitab) and the second inverted bit line (bitbb) is configured to have a second connection line (Cb2) formed on the same layer (Ly1,Ly2) as the other of the first inverted bit line (bitab) and the second inverted bit line (bitbb), so as to be connected to the memory cell (50).

The RAM (100) having the above first structure may have a structure (second structure), in which the first connection line (Cb1) is configured to be shorter than one of the first bit line (bita) and the second bit line (bitb) arranged on the same layer (Ly1,Ly2).

The RAM (100) having the above the above first or second structure may have a structure (third structure), in which the second connection line (Cb2) is configured to be shorter than one of the first inverted bit line (bitab) and the second inverted bit line (bitbb) arranged on the same layer.

The RAM (100) having the above any one of the above first to third structures may have a structure (fourth structure), in which when one of the write operation and the read operation is performed by the first bit line (bita) and the first inverted bit line (bitab), the other of the write operation and the read operation is performed by the second bit line (bitb) and the second inverted bit line (bitbb).

The RAM (100) having any one of the above first to fourth structures may have a structure (fifth structure), in which the first clock signal (CLKA) and the second clock signal (CLKB) are output in one cycle, and the RAM (100) is configured to be capable of performing the write operation to one memory cell (50) and the read operation from another memory cell (50) in the one cycle.

What is claimed is:

1. A RAM comprising:
a plurality of memory cells;
a first bit line and a first inverted bit line connected to each of the plurality of memory cells, so as to be used for a write operation to write information to the memory cell or a read operation to read information, on the basis of a first clock signal; and
a second bit line and a second inverted bit line connected to each of the plurality of memory cells, so as to be used for the write operation or the read operation, on the basis of a second clock signal different from the first clock signal, wherein
the first bit line and the second bit line are arranged on different layers, and one of the first bit line and the second bit line is configured to have a first connection line formed on the same layer as the other of the first bit line and the second bit line, so as to be connected to the memory cell, and
the first inverted bit line and the second inverted bit line are arranged on different layers, and one of the first inverted bit line and the second inverted bit line is configured to have a second connection line formed on the same layer as the other of the first inverted bit line and the second inverted bit line, so as to be connected to the memory cell.

2. The RAM according to claim 1, wherein the first connection line is configured to be shorter than one of the first bit line and the second bit line arranged on the same layer.

3. The RAM according to claim 1, wherein the second connection line is configured to be shorter than one of the first inverted bit line and the second inverted bit line arranged on the same layer.

4. The RAM according to claim 1, wherein when one of the write operation and the read operation is performed by the first bit line and the first inverted bit line, the other of the write operation and the read operation is performed by the second bit line and the second inverted bit line.

5. The RAM according to claim 4, wherein the first clock signal and the second clock signal are output in one cycle, and the RAM is configured to be capable of performing the write operation to one memory cell and the read operation from another memory cell in the one cycle.
